(19) United States
(12) Patent Application Publication
(10) Pub. No.: US 2025/0372380 A1
(43) Pub. Date: Dec. 4, 2025

(54) METHOD OF MANUFACTURING SEMICONDUCTOR DEVICE

(71) Applicant: Samsung Electronics Co., Ltd., Suwon-si (KR)

(72) Inventors: Janghoon KIM, Suwon-si (KR); Woojin JUNG, Suwon-si (KR); Chan HWANG, Suwon-si (KR)

(73) Assignee: Samsung Electronics Co., Ltd., Suwon-si (KR)

(21) Appl. No.: 19/096,959

(22) Filed: Apr. 1, 2025

(30) Foreign Application Priority Data
May 31, 2024 (KR) 10-2024-0071818

(51) Int. Cl. H01L 21/033; H01L 21/308; H10B 12/00

(52) U.S. Cl. CPC H01L 21/0337; H01L 21/0332; H01L 21/308; H10B 12/09

(57) ABSTRACT

A method of manufacturing a semiconductor device includes forming a mask layer structure on a substrate including a first region and a second region, the mask layer structure covering the first region and the second region of the substrate, forming a first photoresist pattern covering at least part of the second region and exposing the first region of the mask layer structure, forming a second photoresist pattern on the mask layer structure and the first photoresist pattern, and etching the mask layer structure by using the first photoresist pattern and the second photoresist pattern.

### CROSS-REFERENCE TO RELATED APPLICATION

This application is based on and claims priority under 35 U.S.C. § 119 to Korean Patent Application No. 10-2024-0071818, filed on May 31, 2024, in the Korean Intellectual Property Office, the disclosure of which is incorporated by reference herein in its entirety.

### BACKGROUND

Example embodiments of the inventive concepts relate to methods of forming patterns in semiconductor devices.

With the development of electronics technology, down-scaling of integrated circuit devices is progressing rapidly, and feature sizes of the integrated circuit devices are being reduced. Accordingly, it is desirable for semiconductor device structures to include unit elements having improved electrical reliability in a peripheral circuit region including a cell array region and a core region adjacent to the cell array region.

### SUMMARY

According to some example embodiments of the inventive concepts, a method of manufacturing a semiconductor device includes forming a mask layer structure covering a first region and a second region of a substrate, forming a first photoresist pattern covering at least a part of the second region and exposing the first region of the mask layer structure, forming a second photoresist pattern on the mask layer structure and the first photoresist pattern, and etching the mask layer structure by using the first photoresist pattern and the second photoresist pattern.

According to some example embodiments of the inventive concepts, a method of manufacturing a semiconductor device includes forming a mask layer structure covering a first region and a second region of a substrate, the mask layer structure including a mask layer, a buffer layer, a first mandrel layer, and a second mandrel layer sequentially stacked, forming a first photoresist pattern covering at least part of the second region and exposing the first region of the mask layer structure, forming a second photoresist pattern on the mask layer structure and the first photoresist pattern, forming a first mandrel pattern by patterning the second mandrel layer by using the first photoresist pattern and the second photoresist pattern, forming a first spacer covering a sidewall of the first mandrel pattern and forming a second mandrel pattern by patterning the first mandrel layer by using the first spacer, forming a second spacer covering a sidewall of the second mandrel pattern and forming a mask pattern by patterning the buffer layer and the mask layer by using the second spacer, etching the mask pattern, and forming an active pattern on the substrate by using the etched mask pattern as an etch mask.

According to some example embodiments of the inventive concepts, a method of manufacturing a semiconductor device includes forming a mask layer structure covering a memory cell region and a peripheral circuit region of a substrate, the mask layer structure including a mask layer, a buffer layer, a first mandrel layer, and a second mandrel layer sequentially stacked, and the substrate further including a boundary region surrounding the memory cell region and an extension region spaced apart from the memory cell region with the boundary region therebetween, forming a first photoresist pattern on the mask layer structure in the extension region and exposing the memory cell region of the mask layer structure, forming a second photoresist pattern on the mask layer structure and the first photoresist pattern, forming a first mandrel pattern by patterning the second mandrel layer by using the first photoresist pattern and the second photoresist pattern, forming a first spacer covering a sidewall of the first mandrel pattern and forming a second mandrel pattern by patterning the first mandrel layer by using the first spacer, forming a second spacer covering a sidewall of the second mandrel pattern and form a mask pattern by patterning the buffer layer and the mask layer by using the second spacer, etching the mask pattern, and forming an active pattern on the substrate by using the etched mask pattern as an etch mask.

### BRIEF DESCRIPTION OF THE DRAWINGS

Example embodiments of the inventive concepts will be more clearly understood from the following detailed description taken in conjunction with the accompanying drawings in which:

FIGS. 1, 2A, 2B, 3A, 3B, 4A, 4B, 5, 6A, 6B, 7, 8, 9, 10, 11, 12, and 13 are cross-sectional views and plan views illustrating a method of manufacturing a semiconductor device, according to some example embodiments.

FIG. 14A is a preliminary pattern obtained after etching operation on the semiconductor device structure in FIG. 13.

FIG. 14B is a pattern obtained after etching operation using the preliminary pattern of FIG. 14A.

FIG. 15 is a plan view illustrating a semiconductor device, according to some example embodiments.

FIG. 16 is a cross-sectional view illustrating a first region of the semiconductor device illustrated in FIG. 15.

### DETAILED DESCRIPTION

Hereinafter, example embodiments of the inventive concepts are described in detail with reference to the attached drawings. The same reference numerals are used for the same components in the drawings, and descriptions thereof are not repeated for the sake of brevity.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

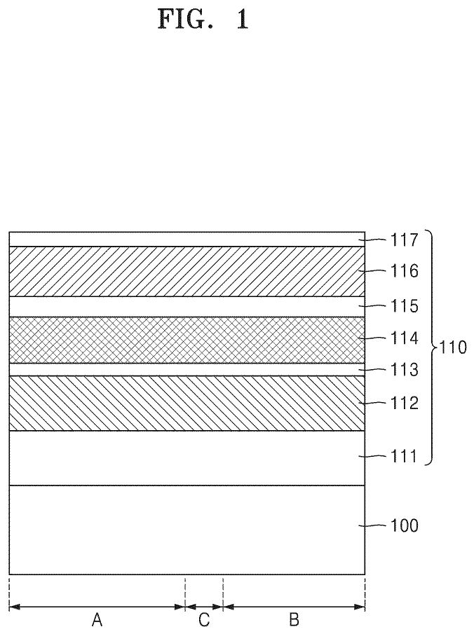

FIGS. 1 to 14 are cross-sectional views and plan views illustrating a method of manufacturing a semiconductor device, according to some example embodiments.

Referring to FIG. 1, a substrate 100 including a first region A and a second region may be provided. The first region A may refer to a memory cell region where memory cells of a semiconductor device are formed. A second region may refer to a peripheral circuit region where logic cells and bulky patterns, such as align keys and/or photo keys, are formed. In some example embodiments, the peripheral circuit region may include an extension region B and a boundary region C. The boundary region C may surround the first region A, and the extension region B may be spaced apart from the first region A with the boundary region C therebetween. In the following description, the first region A and the second region (including the extension region B and the boundary region C) may each include a surface of the substrate 100 and regions perpendicular to the surface of the substrate 100.

In some example embodiments, the substrate 100 may include silicon (Si), crystalline Si, polycrystalline Si, or amorphous Si. In some example embodiments, the substrate 100 may include a semiconductor material, such as germanium (Ge), or at least one compound semiconductor selected from among silicon germanium (SiGe), silicon carbide (SiC), gallium arsenide (GaAs), indium arsenide (InAs), and indium phosphide (InP). In some example embodiments, the substrate 100 may have a silicon on insulator (SOI) structure. For example, the substrate 100 may include a buried oxide layer (BOX) layer. The substrate 100 may include a conductive region, for example, a well doped with an impurity, and/or a structure doped with an impurity.

Thereafter, a mask layer structure 110 including a stack of multiple layers as etch mask layers may be formed on the substrate 100. In some example embodiments, the mask layer structure 110 may include a first mask layer 111, a second mask layer 112, a buffer layer 113, a first mandrel layer 114, a first separation layer 115, a second mandrel layer 116, and a second separation layer 117. The first mask layer 111, the second mask layer 112, the buffer layer 113, the first mandrel layer 114, the first separation layer 115, the second mandrel layer 116, and the second separation layer 117 may be sequentially stacked on the substrate 100. However, the layers included in the mask layer structure 110 are not limited thereto. Among the layers included in the mask layer structure 110, layers in lower portions may each have an etch selectivity to each other.

In some example embodiments, the first mask layer 111 may be configured to etch the substrate 100. The first mask layer 111 may include a material with an etch selectivity to the substrate 100. For example, the first mask layer 111 may be or include a silicon oxide layer.

In some example embodiments, the second mask layer 112 may be configured to pattern the first mask layer 111. The second mask layer 112 may include a material with an etch selectivity to the first mask layer 111. For example, the second mask layer 112 may be or include polysilicon.

In some example embodiments, the buffer layer 113 may be configured to reduce defects caused by the electrical conductivity of the second mask layer 112 under the buffer layer 113. The buffer layer 113 may include a material with lower electrical conductivity than the second mask layer 112. The buffer layer 113 may be provided as part of an etch mask for etching the second mask layer 112. Accordingly, the buffer layer 113 may include a material with an etch selectivity to the second mask layer 112. For example, the buffer layer 113 may be or include silicon oxide or silicon oxynitride.

In some example embodiments, the buffer layer 113 may be between the second mask layer 112 and the first mandrel layer 114. The buffer layer 113 may have a thickness less than thicknesses of the second mask layer 112 and the first mandrel layer 114. In some example embodiments, the buffer layer 113 may have a thickness of 50 Å or about 50 Å to 300 Å or about 300 Å. For example, the second mask layer 112 may have a thickness of 500 Å or about 500 Å, the first mandrel layer 114 may have a thickness of 500 Å or about 500 Å, and the buffer layer 113 may have a thickness of 135 Å about 135 Å. In some example embodiments, the buffer layer 113 may be formed using atomic layer deposition (ALD).

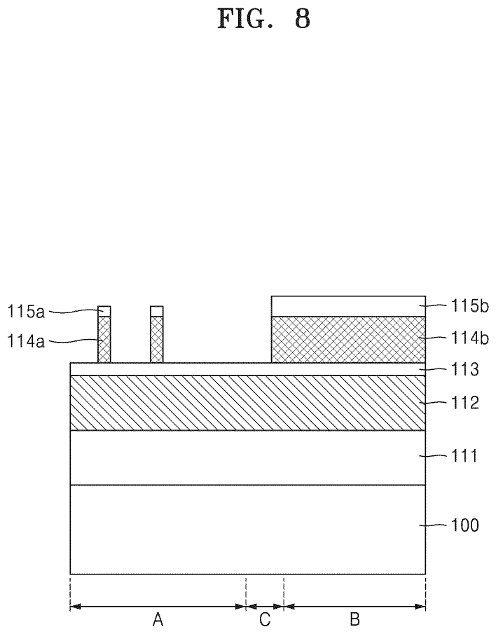

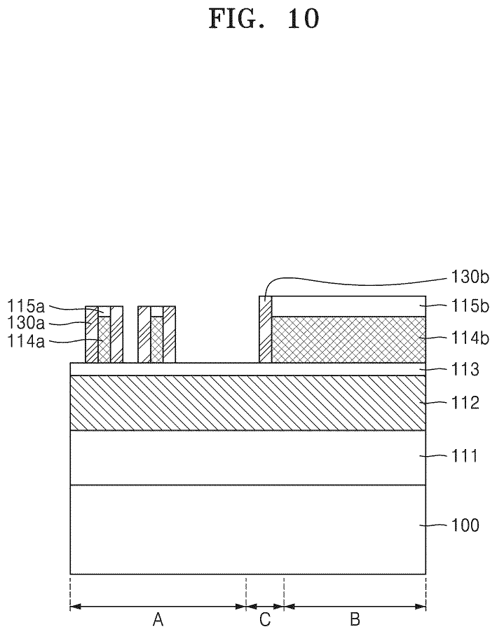

In some example embodiments, the buffer layer 113 may include the same material as a second spacer 130a (see FIG. 10) formed on a sidewall of a third mandrel pattern 114a (see FIG. 8) in the subsequent process. In some example embodiments, the second spacer 130a may be configured as an etch mask for patterning the second mask layer 112.

In some example embodiments, the second spacer 130a may include silicon oxide, and the buffer layer 113 may include silicon oxide or silicon oxynitride. Hereinafter, at least one example embodiment is described considering the second spacer 130a and the buffer layer 113 are made of or include silicon oxide.

In some example embodiments, the first mandrel layer 114 may be or include a material with an etch selectivity to the second spacer 130a. Also, the first mandrel layer 114 may be a sacrificial layer used to form the second spacer 130a, and accordingly, the first mandrel layer 114 may include a material that may be removed with relative ease. In some example embodiments, the first mandrel layer 114 may be or include an amorphous carbon layer (ACL).

In some example embodiments, the first separation layer 115 may be or include silicon oxynitride. The first separation layer 115 may have a thickness less than the first mandrel layer 114. For example, a thickness of the first mandrel layer 114 may be 500 Å or about 500 Å, and a thickness of the first separation layer 115 may be 350 Å or about 350 Å.

In some example embodiments, the second mandrel layer 116 may include a spin-on hard mask material. The spin-on hard mask material may be or include amorphous carbon. Accordingly, in order to distinguish the first mandrel layer 114 and the second mandrel layer 116 from each other, the first separation layer 115 may be between the first mandrel layer 114 and the second mandrel layer 116.

In some example embodiments, the second separation layer 117 may be or include silicon oxynitride. The second separation layer 117 may have a thickness less than the second mandrel layer 116. For example, a thickness of the second mandrel layer 116 may be 700 Å or about 700 Å, and a thickness of the second separation layer 117 may be 260 Å or about 260 Å.

In some example embodiments, the first separation layer 115 and/or the second separation layer 117 may be provided to distinguish an upper layer and a lower layer from each other. In some example embodiments, the first separation layer 115 and the second separation layer 117 may function as anti-reflection layers.

Hereinafter, a method of forming active patterns using a quadruple patterning technique (QPT) process, according to some example embodiments, is described. However, the method of forming the active patterns is not limited thereto, and the active patterns may be formed using other techniques, for example, a double patterning technique (DPT) process.

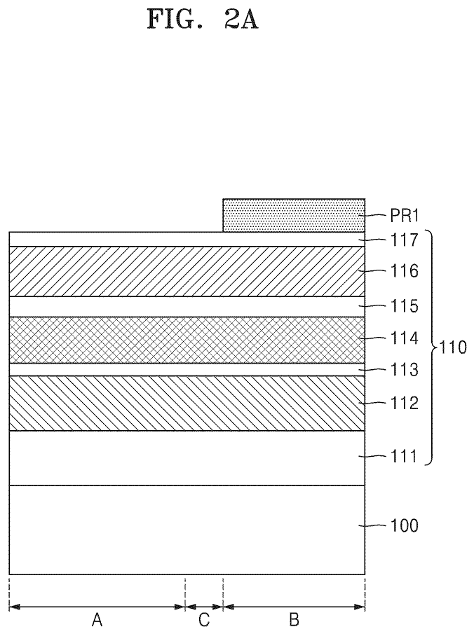

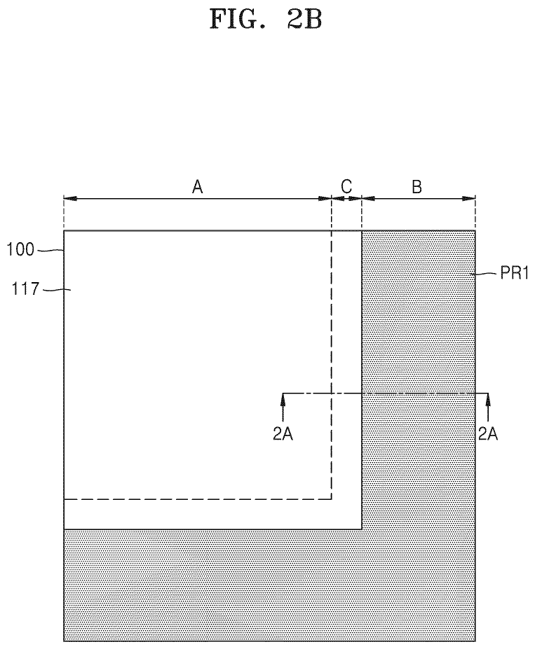

FIG. 2A is a cross-sectional view taken along 2A-2A in the plan view illustrated in FIG. 2B. Referring to FIGS. 2A and 2B, a first photoresist pattern PR1 may be formed in part of a second region of the mask layer structure 110. For example, the first photoresist pattern PR1 may be formed in the extension region B of the mask layer structure 110.

A process of forming the first photoresist pattern PR1 may include a process of baking the first photoresist pattern PR1 at a high temperature. The process of baking the first photoresist pattern PR1 may be performed in a range of 170° C. or about 170° C. to 240° C. about 240° C. For example, the first photoresist pattern PR1 may be cured after being processed at a high temperature of 170° C. or about 170° C. or higher.

In some example embodiments, the first photoresist pattern PR1 may be or include a KrF photoresist material. Also, a thickness of the first photoresist pattern PR1 may be in a range of 1000 Å or about 1000 Å to 3000 Å or about 3000 Å. In some example embodiments, when the thickness of the first photoresist pattern PR1 is 1000 Å or about 1000 Å, a slope of a sidewall of the first photoresist pattern PR1 may have a lesser effect on subsequent fabrication processes. In a subsequent etch process of the second mandrel layer 116, ion scattering due to a step difference of the first photoresist pattern PR1 may be reduced or minimized, and accordingly, patterns may be formed more precisely or satisfactorily.

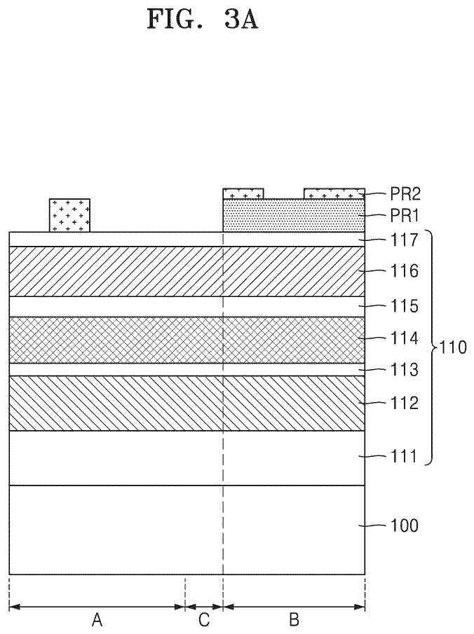

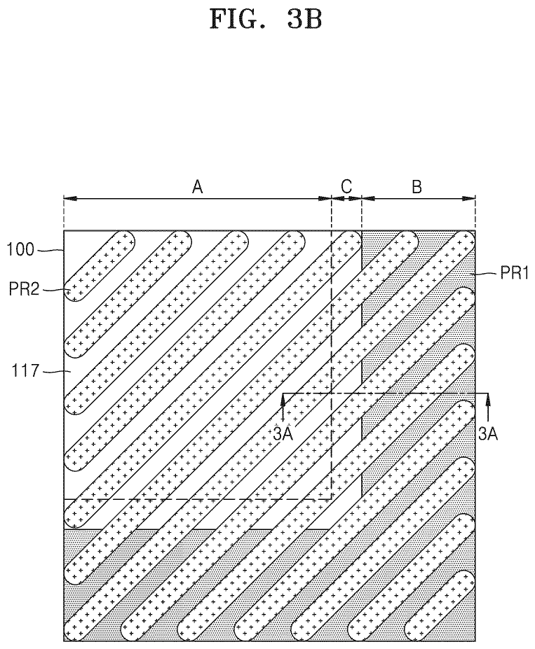

In some example embodiments, the first photoresist pattern PR1 may cover the entire mask layer structure 110 in the second region and a width of the first photoresist pattern PR1 may be greater than a width of a second photoresist pattern PR2 (see FIG. 3B), which is described below.

FIG. 3A is a cross-sectional view taken along line 3A-3A in the plan view illustrated in FIG. 3B. Referring to FIGS. 3A and 3B, the second photoresist pattern PR2 may be formed in the first region A and the second region of the mask layer structure 110. In some example embodiments, the second photoresist pattern PR2 may include a different material from the first photoresist pattern PR1, but example embodiments are not limited thereto.

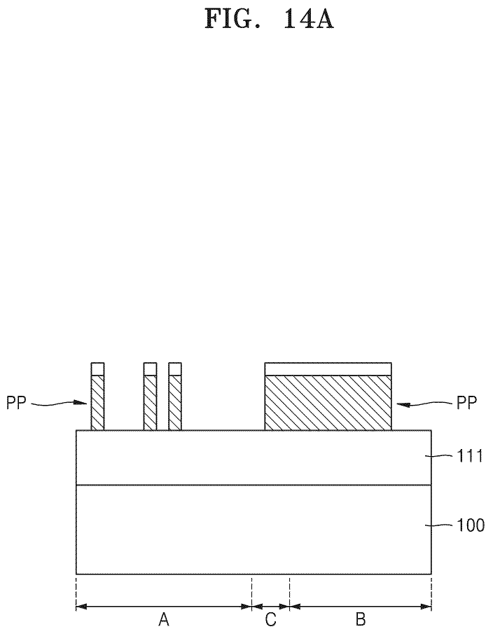

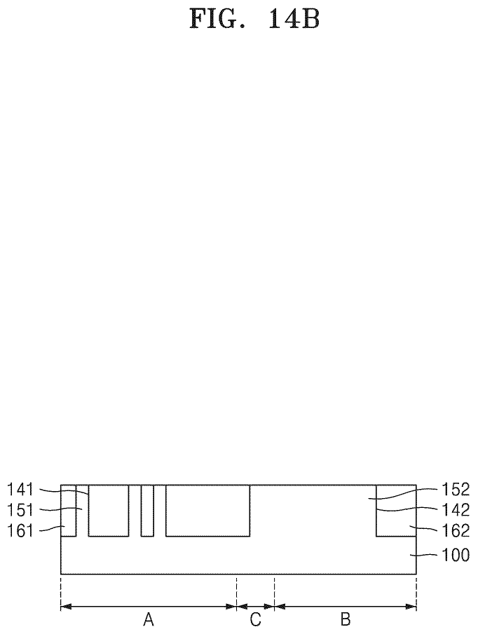

In some example embodiments, the second photoresist pattern PR2 may be or have a line shape extending in one direction. A plurality of second photoresist patterns PR2 may be arranged in one direction and spaced apart from each other in parallel. The second photoresist pattern PR2 may have a line width that is about three times the first line width, which is a target line width of a first active pattern 151 (see FIG. 14). Also, a gap portion between the second photoresist patterns PR2 may have a line width of about 5 times the first line width.

In some example embodiments, the second photoresist pattern PR2 may be formed in both the first region A and the second region. In some example embodiments, a thickness (e.g., vertical dimension in FIG. 3A) of the second photoresist pattern PR2 formed on the second separation layer 117 in the first region A may be greater than a thickness of the second photoresist pattern PR2 formed on the first photoresist pattern PR1 in the extension region B.

As described above, by curing the first photoresist pattern PR1 after being processed at a high temperature, the first photoresist pattern PR1 may be retained during formation of the second photoresist pattern PR2.

Although FIGS. 2A and 3A illustrate that a sidewall of the first photoresist pattern PR1 is vertical and is located in the extension region B, example embodiments are not limited thereto. In some example embodiments, the sidewall of the first photoresist pattern PR1 may have a preset or desired slope. Portions of the first photoresist pattern PR1 may be formed on the boundary region C. Likewise, a sidewall of the second photoresist pattern PR2 may have a preset or desired slope. Portions of the second photoresist pattern PR2 may be formed on the boundary region C.

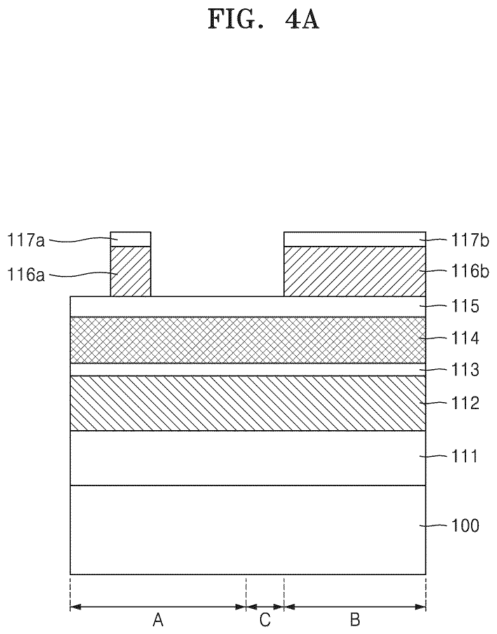

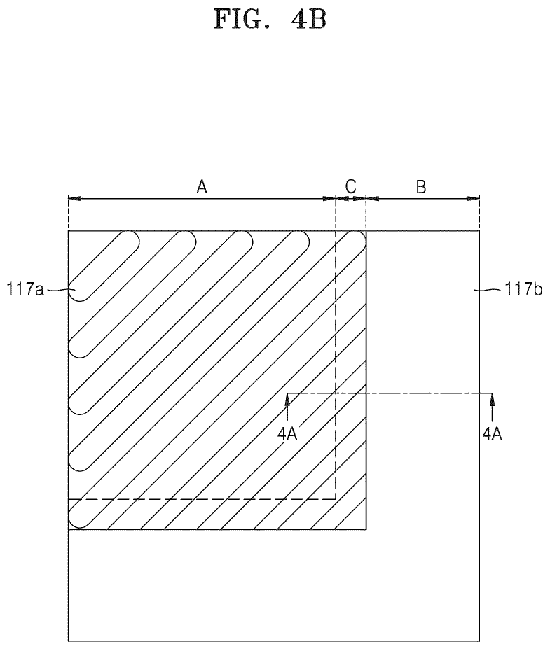

FIG. 4A is a cross-sectional view taken along line 4A-4A in the plan view illustrated in FIG. 4B. Referring to FIGS. 4A and 4B, the second separation layer 117 and the second mandrel layer 116 are sequentially etched by using the first photoresist pattern PR1 and the second photoresist pattern PR2 as an etch mask. As a result, a first mandrel pattern 116a and a first separation pattern 117a may be formed over the first separation layer 115 in the first region A, and a second mandrel pattern 116b and a second separation pattern 117b may be formed over the first separation layer 115 in the extension region B. The first mandrel pattern 116a and the first separation pattern 117a may also be partially formed over the first separation layer 115 in the boundary region C. The first photoresist pattern PR1 and the second photoresist pattern PR2 may then be removed after the etching operation.

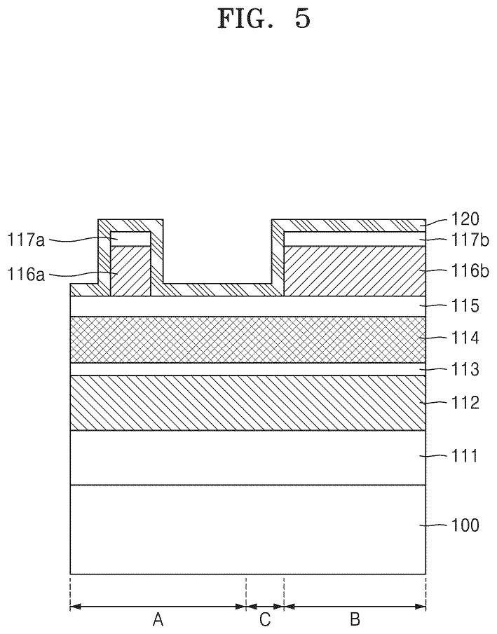

Referring to FIG. 5, the first mandrel pattern 116a, the first separation pattern 117a, the second mandrel pattern 116b, the second separation pattern 117b, and the first separation layer 115 may be conformally covered by a first spacer layer 120.

In some example embodiments, the first spacer layer 120 may be provided as an etch mask for etching the first separation layer 115 and the first mandrel layer 114 formed thereunder. In some example embodiments, the first spacer layer 120 may be or include silicon oxide.

In some example embodiments, the first spacer layer 120 may be deposited to have a thickness equal to a first line width. In order to control a thickness of the first spacer layer 120 during deposition, the first spacer layer 120 may be formed using ALD.

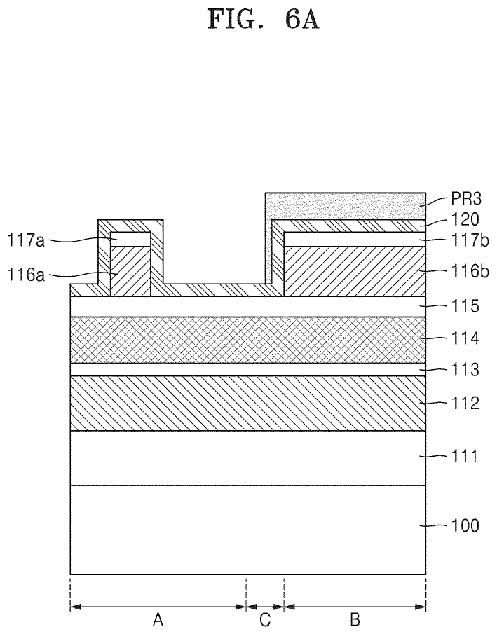

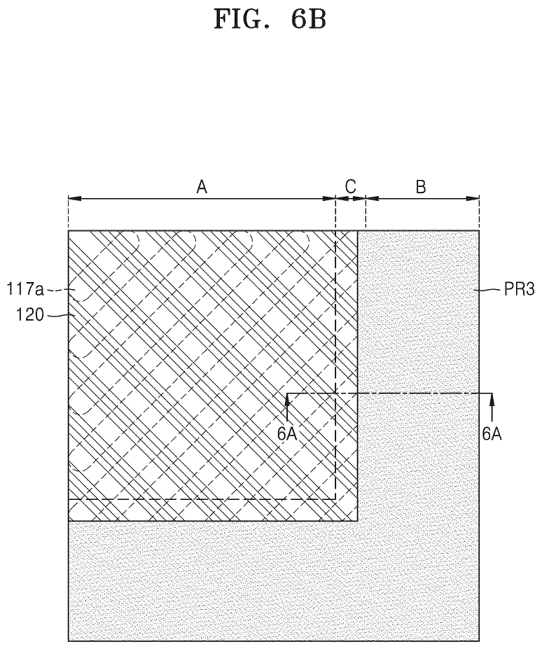

FIG. 6A is a cross-sectional view taken along line 6A-6A in the plan view illustrated in FIG. 6B. Referring to FIGS. 6A and 6B, a third photoresist pattern PR3 may be formed on the first spacer layer 120. The third photoresist pattern PR3 may cover the first spacer layer 120 formed on surfaces of the second mandrel pattern 116b and the second separation pattern 117b.

In some example embodiments, the third photoresist pattern PR3 may cover the extension region B. The third photoresist pattern PR3 may not be formed on the first region A. The third photoresist pattern PR3 may partially cover the boundary region C and selectively expose part of the boundary region C. For example, and as illustrated in FIG. 6A, the third photoresist pattern PR3 may cover the sidewalls of the first spacer layer 120 in the boundary region C.

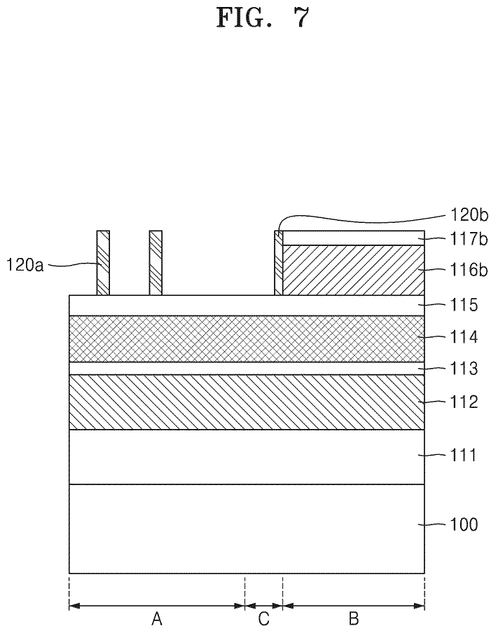

Referring to FIG. 7, a first spacer 120a may be formed on sidewalls of the first mandrel pattern 116a (see FIG. 6A) and the first separation pattern 117a (see FIG. 6A) by anisotropically etching the first spacer layer 120. A first spacer 120a may be formed on the first separation layer 115 in the first region A. The first spacer layer 120 in the extension region B is masked by the third photoresist pattern PR3, and accordingly, the anisotropical etching may not affect the first spacer layer 120 (see FIG. 6A) on the surfaces of the second mandrel pattern 116b and the second separator pattern 117b in the second region and the first spacer layer 120 may be retained.

Thereafter, the first separation pattern 117a and the first mandrel pattern 116a may be selectively removed. Accordingly, first spacers 120a may be arranged on the first separation layer 115 in the first region A and spaced apart from each other. In addition, surfaces of the second mandrel pattern 116b and the second separation pattern 117b in the extension region B are covered with the first spacer layer 120, and thus, the second mandrel pattern 116b and the second separation pattern 117b may be retained during the removal process. The process of removing the first mandrel pattern 116a may include an ashing process.

Thereafter, the first spacer layer 120 on upper surfaces of the second mandrel pattern 116b and the second separation pattern 117b may be removed. In this case, part of a first sidewall spacer 120b may remain on one sidewall of each of the second mandrel pattern 116b and the second separation pattern 117b in a boundary of the extension region B.

Referring to FIG. 8, the first separation layer 115 exposed between the first spacers 120a may be anisotropically etched by using the first spacer 120a as an etch mask, and then the first mandrel layer 114 may be etched. Accordingly, a structure in which a third mandrel pattern 114a and a third separation pattern 115a are stacked may be formed on the buffer layer 113 in the first region A.

When an etching process is performed, the second separation pattern 117b and the second mandrel pattern 116b in the extension region B may be removed. In addition, as the second separation pattern 117b and the second mandrel pattern 116b in the extension region B are used as an etch mask, a structure in which a fourth mandrel pattern 114b and a fourth separation pattern 115b are stacked may be formed on the buffer layer 113 in the extension region B.

In this way, in the etching process, different etch masks may be used in the first region A and the extension region B. When an anisotropic etching process is performed, the first spacer 120a in the first region A may be removed rapidly or at a relatively higher rate, and accordingly, some of the upper portions of the third separation pattern 115a in the first region A may be removed. In contrast to this, comparatively lesser material of the fourth separation pattern 115b in the extension region B, which has a greater width than the third separation pattern 115a, may be removed by etching. Accordingly, a thickness of the third separation pattern 115a may be less than a thickness of the fourth separation pattern 115b.

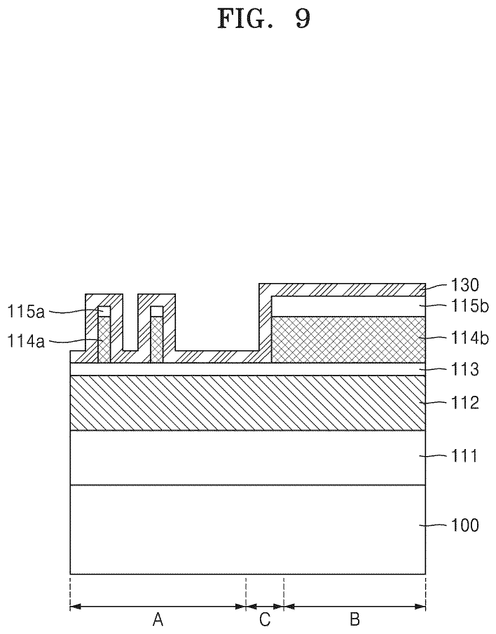

Referring to FIG. 9, the third mandrel pattern 114a, the third separation pattern 115a, the fourth mandrel pattern 114b, the fourth separation pattern 115b, and the buffer layer 113 may be conformally covered by the second spacer layer 130.

In some example embodiments, the second spacer layer 130 may be provided as an etch mask for etching the second mask layer 112. Therefore, the second spacer layer 130 may include a material with an etch selectivity to the second mask layer 112. In some example embodiments, the second spacer layer 130 may be or include silicon oxide.

In some example embodiments, the second spacer layer 130 may be deposited to have a thickness that is substantially equal to the first line width. In order to control a thickness of the second spacer layer 130, the second spacer layer 130 may be formed using ALD.

The second spacer layer 130 may be in direct contact with the buffer layer 113. The second spacer layer 130 may not be in direct contact with the second mask layer 112, which is an etch target layer.

Referring to FIG. 10, the second spacer layer 130 (see FIG. 9) may be anisotropically etched to form the second spacer 130a on sidewalls of the third mandrel pattern 114a and the third separation pattern 115a. Accordingly, in the first region A, the buffer layer 113 may be exposed between the second spacers 130a. Also, an upper surface of the third separation pattern 115a may be exposed.

Also, in an anisotropic etching process, the second spacer layer 130 over the fourth mandrel pattern 114b and the fourth separation pattern 115b in the extension region B may be removed. Thus, an upper surface of the fourth separation pattern 115b may be exposed. Part of the sidewall spacer 130b may remain on one sidewall of each of the fourth mandrel pattern 114b and the fourth separation pattern 115b along a boundary of the extension region B.

A bottom surface of the second spacer 130a may be in direct contact with the buffer layer 113. Therefore, the bottom surface of the second spacer 130a may not be in direct contact with the second mask layer 112, which is an etch target layer.

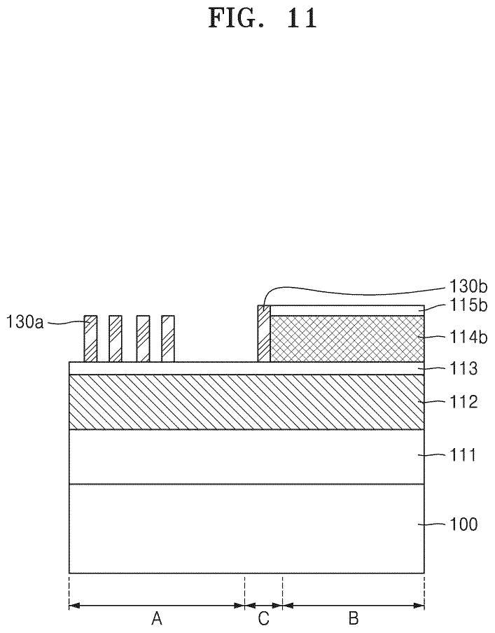

Referring to FIG. 11, both the third mandrel pattern 114a and the third separation pattern 115a may be removed while the fourth separation pattern 115b may be retained. Because the third separation pattern 115a is relatively thinner than the fourth separation pattern 115b, an entirety of the third separation pattern 115a may removed, and only upper portions of the fourth separation pattern 115b may be removed, thereby decreasing the thickness of the fourth separation pattern 115b.

Thereafter, the third mandrel pattern 114a may be selectively removed. The fourth separation pattern 115b covers the fourth mandrel pattern 114b in the extension region B, and accordingly, the fourth mandrel pattern 114b may be retained. The process of removing the third mandrel pattern 114a may include an ashing process. Accordingly, the second spacers 130a formed in the first region A may each have a first line width and be spaced apart from each other by the first line width.

In some example embodiments, the second spacers 130a may be provided as an etch mask for patterning the second mask layer 112. In this case, the buffer layer 113 may include a material with electrical conductivity that is lower than electrical conductivity of the second mask layer 112. The buffer layer 113 may include the same material as the second spacer 130a. For example, the second spacer 130a and the buffer layer 113 may be or include silicon oxide.

The second spacer 130a formed in the first region A may have a first line width and have a line shape extending in the one direction. The second spacers 130a may be spaced apart from each other at intervals equal to the first line width.

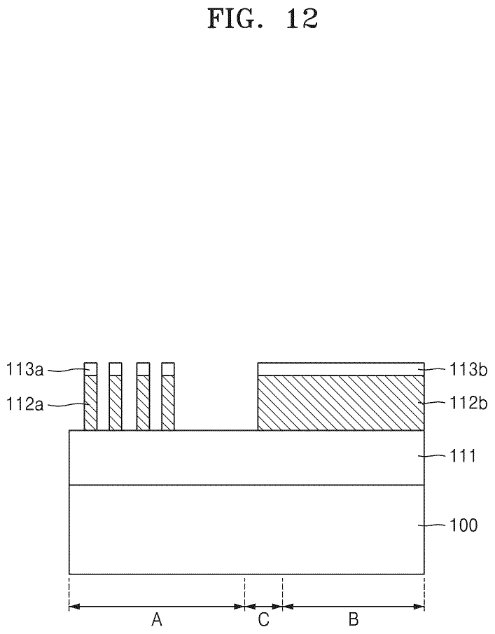

Referring to FIG. 12, the exposed buffer layer 113 may be etched by using the second spacer 130a, the fourth mandrel pattern 114b, the fourth separation pattern 115b, and the sidewall spacer 130b as an etch mask, and accordingly, a first buffer layer pattern 113a and a second buffer layer pattern 113b may be formed. In the process of etching the buffer layer 113, upper portions of the second spacer 130a and the sidewall spacer 130b may also be etched.

Thereafter, the second mask layer 112 may be etched by using the second spacer 130a, the fourth mandrel pattern 114b, the fourth separation pattern 115b, and the sidewall spacer 130b as an etch mask, and accordingly, a first mask pattern 112a may be formed in the first region A, and a second mask pattern 112b may be formed in the extension region B. An upper surface of the first mask layer 111 may be exposed through an opening between first mask patterns 112a, and an upper surface of the first mask layer 111 may be exposed between the first mask pattern 112a and the second mask pattern 112b. When an etching process is performed, the fourth separation pattern 115b and the fourth mandrel pattern 114b may also be removed.

In addition, when the etching process is performed, the first buffer layer pattern 113a in the first region A is removed at a relatively higher rate, and accordingly, a thickness of the first buffer layer pattern 113a in the first region A may be less than that of the second buffer layer pattern 113b in the extension region B.

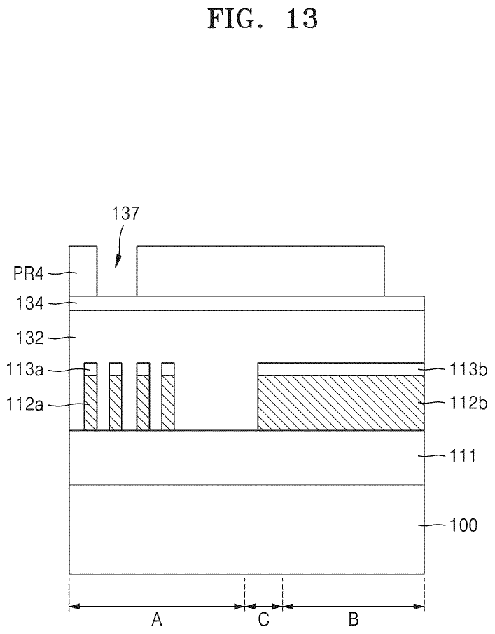

Referring to FIG. 13, a spin-on hard mask layer 132, which covers the first mask pattern 112a and the second mask pattern 112b, may be formed. A third separation layer 134 may be formed on the spin-on hard mask layer 132. The third separation layer 134 may be or include silicon oxynitride.

Thereafter, a fourth photoresist pattern PR4 may be formed on the third separation layer 134. The fourth photoresist pattern PR4 may include an opening 137 that selectively exposes portions over the first mask pattern 112a. As discussed below, the first mask pattern 112a may be etched to form the first active pattern 151 (see FIG. 14) in the first region A of the substrate 100. Also, a portion formed as a second device isolation pattern in the second region may be selectively exposed.

FIG. 14A is a preliminary pattern obtained after etching operation on the semiconductor device structure in FIG. 13. FIG. 14B is a pattern obtained after etching operation using the preliminary pattern of FIG. 14A. Referring to FIG. 14A, the third separation layer 134 may be anisotropically etched by using the fourth photoresist pattern PR4 as an etch mask. Subsequently, the spin-on hard mask layer 132 may be anisotropically etched. Also, exposed portions of the first buffer layer pattern 113a, the second buffer layer pattern 113b, the first mask pattern 112a, and the second mask pattern 112b may be partially and anisotropically etched. Thereafter, the fourth photoresist pattern PR4, the third separation layer 134, and the spin-on hard mask layer 132 may be removed.

Thereafter, the first mask layer 111 may be etched by using the first buffer layer pattern 113a, the second buffer layer pattern 113b, the first mask pattern 112a, and the second mask pattern 112b, which may be retained, as an etch mask, and accordingly, a preliminary pattern PP may be formed.

Referring to FIG. 14B, an upper portion of the substrate 100 may be etched by using the preliminary pattern PP as an etch mask. Accordingly, a first trench 141 and the first active pattern 151 may be formed in the first region A of the substrate 100. A second trench 142 and a second active pattern 152 may be formed in the second region of the substrate 100.

Thereafter, by filling the inside of the first trench 141 and the second trench 142 with an insulating material and planarizing the insulating material, a fine pattern 140 may be obtained that includes a first device isolation pattern 161 and a second device isolation pattern 162 respectively formed inside the first trench 141 and the second trench 142.

Thereafter, memory cells including gate structures, bit line structures, contact plugs, capacitors, and/or other desired devices or components may be formed on the first active pattern 151 and the first device isolation pattern 161 in the first region A. The memory cells may be dynamic random access memory (DRAM) cells. Also, transistors and wires included in a peripheral circuit may be formed in the second active pattern 152 and the second device isolation pattern 162 in the second region.

In the method of manufacturing a semiconductor device, according to some example embodiments of the inventive concepts, the first photoresist pattern PR1 that does not cover a memory cell region may be formed before the second photoresist pattern PR2 that covers the memory cell region and a peripheral circuit region. Accordingly, an operation of masking the memory cell region during subsequent operations may be omitted. Accordingly, a process of manufacturing a semiconductor device may be simplified and the manufacturing cost may be reduced an/or minimized by omitting several processes including, for example, the process of masking the memory cell region.

In a comparative example in which the masking operation for covering the memory cell region is performed, a spacer covering a first mask pattern is retained, and accordingly, process defects may occur in the process of etching the first mask pattern, resulting in decrease in the reliability of semiconductor devices. In addition, in the method of manufacturing a semiconductor device, according to some example embodiments of the inventive concepts, a masking operation for covering a memory cell region may be omitted by forming the first photoresist pattern PR1 that exposes the memory cell region during initial operations of the manufacturing process. Thus, process defects encountered in the comparative example may be removed and/or minimized, and reliability of semiconductor devices may be increased, maximized and/or improved.

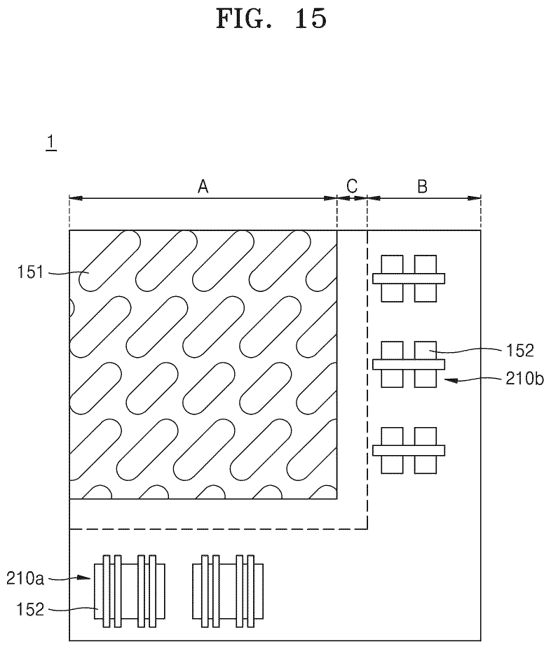

FIG. 15 is a plan view illustrating a semiconductor device, according to some example embodiments.

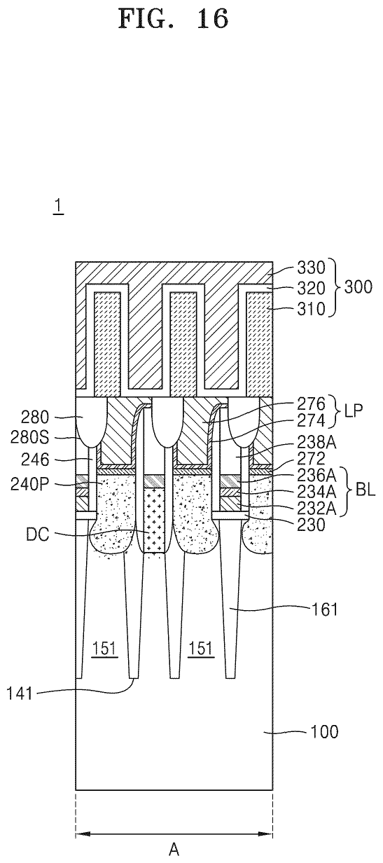

FIG. 16 is a cross-sectional view illustrating a first region of the semiconductor device illustrated in FIG. 15, according to some example embodiments.

FIGS. 15 and 16 may include the first active pattern 151 according to some example embodiments described above. In some example embodiments, the semiconductor device illustrated in FIGS. 15 and 16 may be a DRAM device.

Referring to FIGS. 15 and 16, a semiconductor device 1 may include a substrate 100 including a first region A and a second region. The first region A may refer to a memory cell region where memory cells of the semiconductor device 1 may be formed. The second region may refer to a peripheral circuit region where logic cells and/or bulky patterns, such as align keys or photo keys, may be formed. In some example embodiments, the peripheral circuit region may include an extension region B and a boundary region C. The boundary region C may surround the first region A, and the extension region B may be spaced apart from the first region A with the boundary region C therebetween.

A first device isolation pattern 161 and a first active pattern 151 may be formed in the first region A of the substrate 100. Transistors, gate structures (for example, word lines), bit lines BL, and/or capacitor structures 300 may be formed in the first region A of the substrate 100. A unit memory cell may include one select transistor and one cell capacitor.

The extension region B of the second region (the peripheral circuit region) of the substrate 100 may include transistors, wires, and other peripheral circuits. Circuits 210a, each constituting a sub-word line driver (SWD), and circuits 210b, each constituting a sense amplifier, may be arranged in the extension region B.

Although FIG. 15 illustrates that the first active pattern 151 is formed in the first region A and the second active pattern 152 is formed in the extension region B, example embodiments are not limited thereto. As described above, portions of the first photoresist pattern PR1 (see FIG. 3A) and portions of the second photoresist pattern PR2 (see FIG. 3A) may be formed or extend in the boundary region C. Accordingly, portions of the first active pattern 151 may remain in the boundary region C through the processes described above.

Referring to FIG. 16, the semiconductor device 1 may include the substrate 100 in which a first trench 141 is formed. The first trench 141 may be filled with the first device isolation pattern 161. A plurality of first active patterns 151 may be defined in the substrate 100 by the first trench 141 and the first device isolation pattern 161.

A gate trench extending in a first direction parallel to an upper surface of the substrate 100 may be formed in the substrate 100. A gate structure may be provided inside the gate trench. The gate structure may include a word line. In some example embodiments, the gate structure may include a gate insulating layer, a gate electrode, and a capping insulating pattern. A plurality of gate structures may be formed in a second direction that is parallel to a surface of the substrate 100 and perpendicular to the first direction.

In a plurality of first active patterns 151, a plurality of source/drain regions may be on both sides of the plurality of word lines. The plurality of source/drain regions may each include an impurity region including impurity ions injected into the substrate 100.

The first device isolation pattern 161 may be covered with a buffer insulating layer 230. The buffer insulating layer 230 may be or include an oxide layer, a nitride layer, or a combination thereof. A plurality of direct contacts DC may each be in a partial region of each of the plurality of first active patterns 151. A plurality of bit lines BL may extend in the second direction on the buffer insulating layer 230 and respectively on the plurality of direct contacts DC. The plurality of bit lines BL may be respectively covered with a plurality of insulating capping patterns 238A.

A plurality of conductive plugs 240P may each be arranged in a line between a pair of adjacent bit lines BL among the plurality of bit lines BL. The plurality of conductive plugs 240P arranged in a line may be insulated from each other by an insulating fence. The plurality of conductive plugs 240P may constitute buried contacts.

The plurality of bit lines BL may be respectively connected to the plurality of first active patterns 151 respectively through the plurality of direct contacts DC. One of the plurality of direct contacts DC and a pair of conductive plugs 240P facing each other with the one direct contact DC therebetween may each be connected to different first active patterns 151 among the plurality of first active patterns 151. In some example embodiments, the plurality of direct contacts DC may each be or include Si, Ge, W, WN, Co, Ni, Al, Mo, Ru, Ti, TiN, Ta, TaN, Cu, or a combination thereof. For example, the plurality of direct contacts DC may be composed of an epitaxial silicon layer.

The plurality of bit lines BL may each include a first lower conductive layer 232A, a first intermediate conductive layer 234A, and a first upper conductive layer 236A sequentially formed in the substrate 100. An upper surface of the first lower conductive layer 232A and upper surfaces of the plurality of direct contacts DC may extend on the same plane. Although FIG. 16 illustrates that each of the plurality of bit lines BL has a triple-layer structure including the first lower conductive layer 232A, the first intermediate conductive layer 234A, and the first upper conductive layer 236A, example embodiments are not limited thereto. For example, the plurality of bit lines BL may have a single layer, a double layer, or a structure including four or more stacked layers.

In some example embodiments, the first lower conductive layer 232A may be or include conductive polysilicon. The first intermediate conductive layer 234A and the first upper conductive layer 236A may each be or include TiN, TiSiN, tungsten (W), tungsten silicide, or a combination thereof. For example, the first intermediate conductive layer 234A may be or include TiN and/or TiSiN, and the first upper conductive layer 236A may be or include tungsten (W). The plurality of insulating capping patterns 238A may each be or include of a silicon nitride layer.

The plurality of conductive plugs 240P may each have a pillar shape extending vertically along a space between two of the plurality of bit lines BL in the substrate 100. A bottom surface of each of the plurality of conductive plugs 240P may be in contact with respective one first active pattern 151 of the plurality of first active patterns 151. Part of each of the plurality of conductive plugs 240P may be placed at a lower level than a main surface of the substrate 100. The plurality of conductive plugs 240P may be or include doped polysilicon, metal, conductive metal nitride, or a combination thereof.

Both sidewalls of each of the plurality of bit lines BL, both sidewalls of each of the

plurality of insulating capping patterns 238A, and both sidewalls of each of the plurality of direct contacts DC may be covered with each of a plurality of insulating spacers 246. The plurality of insulating spacers 246 may respectively extend in parallel to the plurality of bit lines BL on both sidewalls of the plurality of bit lines BL. The plurality of insulating spacers 246 may be or include an oxide layer, a nitride layer, an air spacer, or a combination thereof.

Each of a plurality of metal silicide layers 272 and each of a plurality of landing pads LP may be formed sequentially on each of the plurality of conductive plugs 240P. Each of the plurality of metal silicide layers 272 and each of the plurality of landing pads LP may vertically overlap each of the plurality of conductive plugs 240P. Each of the plurality of metal silicide layers 272 may be between each of the plurality of conductive plugs 240P, and each of the plurality of landing pads LP and may be spaced apart from each of the plurality of bit lines BL with each of the plurality of insulating spacers 246 therebetween. The plurality of metal silicide layers 272 may each be or include cobalt silicide, nickel silicide, or manganese silicide.

Each of the plurality of landing pads LP may be connected to respective one of the plurality of conductive plugs 240P through corresponding one of the plurality of metal silicide layers 272. The plurality of landing pads LP may respectively extend from spaces between the plurality of insulating capping patterns 238A to upper spaces of the plurality of insulating capping patterns 238A and are overlapped vertically with part of the plurality of bit lines BL. The plurality of landing pads LP may each include a conductive barrier layer 274 and a conductive layer 276. The conductive barrier layer 274 may be or include Ti, TiN, or a combination thereof. The conductive layer 276 may be or include metal, metal nitride, conductive polysilicon, or a combination thereof. For example, the conductive layer 276 may be or include tungsten (W).

The plurality of landing pads LP may have a plurality of island-like pattern shapes in a plan view. The plurality of landing pads LP may be electrically insulated from each other by a plurality of insulating layers 280 that fill a plurality of insulating spaces 280S around the plurality of landing pads LP. The plurality of insulating layers 280 may each be or include a silicon nitride layer, a silicon oxide layer, or a combination thereof.

A plurality of capacitor structures 300 may be formed on the plurality of landing pads LP and the plurality of insulating layers 280. A plurality of lower electrodes 310, a capacitor dielectric layer 320, and an upper electrode 330 may be sequentially formed. The plurality of lower electrodes 310, the capacitor dielectric layer 320, and the upper electrode 330 may form the plurality of capacitor structures 300. The plurality of lower electrodes 310 may be electrically connected to respective one of the plurality of landing pads LP. The capacitor dielectric layer 320 may conformally cover surfaces of the plurality of lower electrodes 310.

Each of the plurality of lower electrodes 310 may have a column like shape having a circular horizontal cross-section, but example embodiments are not limited thereto and the plurality of lower electrodes 310 may have other shapes depending on application and/or design. In some example embodiments, the plurality of lower electrodes 310 may each have a cylinder shape having a closed lower portion. For example, the plurality of lower electrodes 310 may each be or include a metal doped with an impurity, such as silicon, tungsten, or copper, or a conductive metal compound, such as titanium nitride.

The capacitor dielectric layer 320 may be or include, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb(Zr,Ti)O), (Pb,La)(Zr,Ti)O, Ba(Zr,Ti)O, Sr(Zr,Ti)O, or a combination thereof.

The upper electrode 330 may have a structure of one of a doped semiconductor material layer, a main electrode layer, and an interface layer, or a structure in which at least two of the doped semiconductor material layer, the main electrode layer, and the interface layer are stacked. For example, the doped semiconductor material layer may be or include at least one of doped polysilicon and doped polycrystalline silicon germanium (SiGe). The main electrode layer may be or include a metal. The main electrode layer may be or include, for example, W, Ru, RuO, Pt, PtO, Ir, IrO, SrRuO(SRO), (Ba,Sr)RuO(BSRO), CaRuO (CRO), BaRuO, La(Sr,Co), or so on. In some example embodiments, the main electrode layer may be or include tungsten (W). The interface layer may be or include at least one of metal oxide, metal nitride, metal carbide, and metal silicide.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A method of manufacturing a semiconductor device, the method comprising:
forming a mask layer structure covering a first region and a second region of a substrate;
forming a first photoresist pattern covering at least a part of the second region and exposing the first region of the mask layer structure;
forming a second photoresist pattern on the mask layer structure and the first photoresist pattern; and
etching the mask layer structure by using the first photoresist pattern and the second photoresist pattern.

2. The method of claim 1, wherein the forming of the first photoresist pattern further includes curing the first photoresist pattern.

3. The method of claim 1, wherein the first photoresist pattern includes a different material from the second photoresist pattern.

4. The method of claim 1, wherein the first photoresist pattern is retained when forming of the second photoresist pattern.

5. The method of claim 1, wherein the second photoresist pattern formed on the mask layer structure has a first thickness and the second photoresist pattern formed on the first photoresist pattern has a second thickness, the first thickness being greater than the second thickness.

6. The method of claim 1, wherein
the first region includes a memory cell region,
the second region includes a peripheral circuit region including a boundary region surrounding the first region and an extension region spaced apart from the first region with the boundary region between the first region and the extension region, and
the first photoresist pattern is formed on the mask layer structure in the extension region.

7. The method of claim 1, wherein the etching of the mask layer structure includes:
forming a mask pattern by etching the mask layer structure by using the first photoresist pattern and the second photoresist pattern as an etch mask;
etching the mask pattern; and
forming a fine pattern on the substrate by using the etched mask pattern as an etch mask.

8. The method of claim 1, wherein the first photoresist pattern includes a KrF photoresist material.

9. A method of manufacturing a semiconductor device, the method comprising:
forming a mask layer structure covering a first region and a second region of a substrate, the mask layer structure including a mask layer, a buffer layer, a first mandrel layer, and a second mandrel layer sequentially stacked;
forming a first photoresist pattern covering at least part of the second region and exposing the first region of the mask layer structure;
forming a second photoresist pattern on the mask layer structure and the first photoresist pattern;
forming a first mandrel pattern by patterning the second mandrel layer by using the first photoresist pattern and the second photoresist pattern;
forming a first spacer covering a sidewall of the first mandrel pattern and forming a second mandrel pattern by patterning the first mandrel layer by using the first spacer;
forming a second spacer covering a sidewall of the second mandrel pattern and forming a mask pattern by patterning the buffer layer and the mask layer by using the second spacer;
etching the mask pattern; and
forming an active pattern on the substrate by using the etched mask pattern as an etch mask.

10. The method of claim 9, wherein the forming of the first photoresist pattern further includes curing the first photoresist pattern at a temperature of 170° C. or higher.

11. The method of claim 9, wherein the first photoresist pattern includes a KrF photoresist material.

12. The method of claim 9, wherein the first photoresist pattern is retained when forming the second photoresist pattern.

13. The method of claim 9, wherein the second photoresist pattern formed on the mask layer structure has a first thickness and the second photoresist pattern formed on the first photoresist pattern has a second thickness, the first thickness being greater than the second thickness.

14. The method of claim 9, wherein
the first region includes a memory cell region,
the second region includes a peripheral circuit region including a boundary region surrounding the first region and an extension region spaced apart from the first region with the boundary region between the first region and the extension region, and
the first photoresist pattern is formed on the mask layer structure in the extension region.

15. The method of claim 14, wherein the forming of the second mandrel pattern includes:
forming the first spacer covering the first region and the second region; and
forming a third photoresist pattern covering at least a part of the second region.

16. A method of manufacturing a semiconductor device, the method comprising:
forming a mask layer structure covering a memory cell region and a peripheral circuit region of a substrate, the mask layer structure including a mask layer, a buffer layer, a first mandrel layer, and a second mandrel layer sequentially stacked, and the substrate further including a boundary region surrounding the memory cell region and an extension region spaced apart from the memory cell region with the boundary region therebetween;
forming a first photoresist pattern on the mask layer structure in the extension region and exposing the memory cell region of the mask layer structure;
forming a second photoresist pattern on the mask layer structure and the first photoresist pattern;
forming a first mandrel pattern by patterning the second mandrel layer by using the first photoresist pattern and the second photoresist pattern;
forming a first spacer covering a sidewall of the first mandrel pattern and forming a second mandrel pattern by patterning the first mandrel layer by using the first spacer;
forming a second spacer covering a sidewall of the second mandrel pattern and form a mask pattern by patterning the buffer layer and the mask layer by using the second spacer;
etching the mask pattern; and
forming an active pattern on the substrate by using the etched mask pattern as an etch mask.

17. The method of claim 16, wherein the forming of the active pattern includes forming a first active pattern in the memory cell region and at least in part of the boundary region.

18. The method of claim 16, wherein the first photoresist pattern is retained when forming of the second photoresist pattern.

19. The method of claim 16, wherein the forming of the active pattern includes:
forming a first active pattern in the memory cell region; and
forming, in the peripheral circuit region, a second active pattern having a greater line width than the first active pattern.

20. The method of claim 16, wherein the first photoresist pattern includes a KrF photoresist material.
